(19) United States
(12) Patent Application Publication
(10) Pub. No.: US 2025/0300449 A1
(43) Pub. Date: Sep. 25, 2025

(54) BATTERY DISCONNECTION SYSTEM AND FAILURE DETECTION METHOD

(71) Applicant: Panasonic Intellectual Property Management Co., Ltd., Osaka (JP)

(72) Inventors: EIICHI SADAYUKI, Osaka (JP); HIDEKI IWAKI, Osaka (JP)

(21) Appl. No.: 18/863,672

(22) PCT Filed: Apr. 5, 2023
(86) PCT No.: PCT/JP2023/014046

§ 371 Date: Nov. 7, 2024

(30) Foreign Application Priority Data
May 26, 2022 (JP) 2022-086313

(51) Int. Cl. H02H 7/18; H02J 7/00

(52) U.S. Cl. CPC H02H 7/18; H02J 7/0031; H02J 7/0047

(57) ABSTRACT

A battery disconnection system includes: a main relay connected between a battery and a load; a pre-charge relay and a pre-charge resistor connected in parallel to the main relay and connected in series; a current sensor that measures a current of the battery; a pyrotechnic disconnection device that cuts off the current of the battery; a voltage measurement unit that measures a voltage of the pre-charge resistor; and a control circuit. The control circuit controls the pyrotechnic disconnection device based on a measured value of the current sensor when the main relay is turned on, and detects a failure of the current sensor based on a measured value of the voltage measurement unit when the main relay is turned off and the pre-charge relay is turned on.

### TECHNICAL FIELD

### Battery Disconnection System and Failure Detection Method

### BACKGROUND ART

Patent Literature 1 describes a system that causes a fuse to interrupt a flow of current on the basis of a detected current detected by a current sensor.

### CITATION LIST

### Patent Literature

PTL 1: Unexamined Japanese Patent Publication No. 2015-91199

### SUMMARY OF THE INVENTION

In the system described in Patent Literature 1, in a case where the current sensor fails, there is a case where an overcurrent is not flowing but is erroneously disconnected due to erroneous detection of the current, or an overcurrent is flowing but is not disconnected. For example, in order to detect a failure of the current sensor, it is conceivable to provide a plurality of current sensors for redundancy, but the cost increases.

Therefore, the present disclosure provides a battery disconnection system or the like that can detect a failure of a current sensor without providing a plurality of current sensors.

A battery disconnection system according to an aspect of the present disclosure includes: a main relay connected between a battery and a load; a pre-charge relay connected in parallel to the main relay: a pre-charge resistor connected in parallel to the main, the pre-charge relay and the pre-charge resistor connected in series; a current sensor that measures a current of the battery; a pyrotechnic disconnection device that cuts off the current of the battery; a voltage measurement unit that measures a voltage of the pre-charge resistor; and a control circuit. The control circuit controls the pyrotechnic disconnection device based on a measured value of the current sensor when the main relay is turned on, and detects a failure of the current sensor based on a measured value of the voltage measurement unit when the main relay is turned off and the pre-charge relay is turned on.

A failure detection method according to an aspect of the present disclosure is a failure detection method of a current sensor executed by a battery disconnection system including a main relay connected between a battery and a load, a pre-charge relay and a pre-charge resistor connected in parallel to the main relay and connected in series, a current sensor that measures a current of the battery, and a pyrotechnic disconnection device that cuts off a current of the battery, the failure detection method including the steps of: measuring a voltage of the pre-charge resistor when the main relay is turned off and the pre-charge relay is turned on; and detecting a failure of the current sensor based on the measured values measured in the step of measuring.

According to the battery disconnection system or the like according to an aspect of the present disclosure, a failure of the current sensor can be detected without providing a plurality of current sensors.

### BRIEF DESCRIPTION OF THE DRAWINGS

FIG. 1 is a configuration diagram illustrating an example of a battery disconnection system according to a first exemplary embodiment.

FIG. 2 is a configuration diagram illustrating an example of a battery disconnection system according to a modification of the first exemplary embodiment.

FIG. 3 is a configuration diagram illustrating an example of a battery disconnection system according to a second exemplary embodiment.

FIG. 4 is a configuration diagram illustrating an example of a battery disconnection system according to a modification of the second exemplary embodiment.

FIG. 5 is a flowchart illustrating an example of a failure detection method according to another exemplary embodiment.

### DESCRIPTION OF EMBODIMENT

Hereinafter, an exemplary embodiment will be specifically described with reference to the drawings.

Note that the exemplary embodiments described below illustrate comprehensive or specific examples. Numerical values, shapes, materials, constituent elements, disposition positions and connection forms of the constituent elements, and the like described in the following exemplary embodiments are illustrative, and are not intended to limit the scope of the present disclosure.

### First Exemplary Embodiment

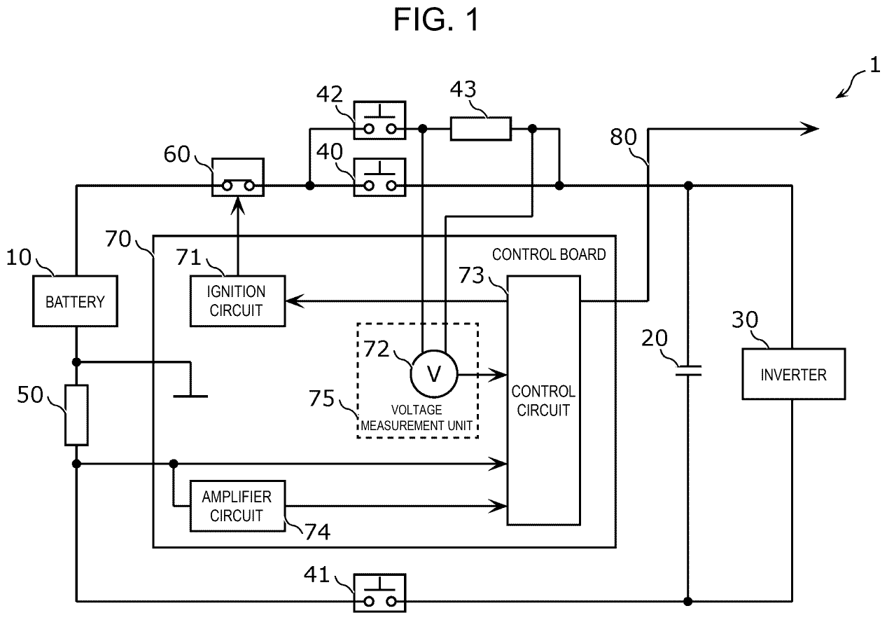

Hereinafter, battery disconnection system 1 according to a first exemplary embodiment will be described with reference to FIG. 1.

FIG. 1 is a configuration diagram illustrating an example of a battery disconnection system 1 according to a first exemplary embodiment. FIG. 1 illustrates battery 10, smoothing capacity 20, and inverter 30 in addition to battery disconnection system 1. Battery 10, smoothing capacity 20, or inverter 30 may be a component of battery disconnection system 1.

Battery disconnection system 1 is mounted on, for example, a vehicle such as an electric vehicle that uses electric power for propulsion drive. High-voltage battery 10 is mounted on a vehicle such as an electric vehicle, and electric power is supplied from the battery 10 to a load to propel and drive the vehicle such as the electric vehicle. When an accident or the like occurs, a large current due to an abnormality such as a short circuit may flow in a path connecting battery 10 and the load, and battery 10 may smoke or fire. Therefore, battery disconnection system 1 is provided to disconnect the path. Hereinafter, smoothing capacity 20 and inverter 30 are illustrated as examples of the load.

Smoothing capacity 20 smooths the current from battery 10, and inverter 30 converts the direct current from battery 10 into the alternating current. As a result, the motor can be driven by the alternating current to propel the vehicle.

Battery disconnection system 1 includes main relays 40 and 41, pre-charge relay 42, pre-charge resistor 43, current sensor 50, pyrotechnic disconnection device 60, and control board 70. Control board 70 is provided with ignition circuit 71, control circuit 73, amplifier circuit 74, voltage measurement unit 75, communication interface 80, and the like.

Main relays 40 and 41 are provided on a path connecting battery 10 and the load, and can supply power from battery 10 to the load when main relays 40 and 41 are turned on. Note that, that the relay is turned on means that the relay is in a conductive state, and that the relay is turned off means that the relay is in a non-conductive state.

When both main relays 40 and 41 are turned on at the time of starting the vehicle or the like, an inrush current flows. Therefore, battery disconnection system 1 is provided with pre-charge relay 42 and pre-charge resistor 43 as countermeasures against an inrush current.

Pre-charge relay 42 and pre-charge resistor 43 are connected in series, and a circuit in which pre-charge relay 42 and pre-charge resistor 43 are connected in series is connected in parallel with main relay 40. For example, when the vehicle is started, main relay 40 is turned off, main relay 41 is turned on, and pre-charge relay 42 is turned on. As a result, a current flows to the load via pre-charge resistor 43, so that generation of an inrush current can be suppressed. For example, in about 0.1 s, the voltage of smoothing capacity 20 becomes substantially the same as the voltage of battery 10, pre-charge relay 42 is turned off, main relay 40 is turned on, and the normal operation is started. For example, main relays 40 and 41 and pre-charge relay 42 are controlled by an electronic control unit (ECU) or the like outside battery disconnection system 1.

Main relays 40, 41 and pre-charge relay 42 are mechanical relays (contact relays). In the present exemplary embodiment, other types of relays (as an example, a semiconductor relay and a contactless relay) can be used as main relays 40, 41 and pre-charge relay 42. However, in order to reliably switch between disconnection and supply of a large current from a large-capacity battery mounted on an electric vehicle such as a hybrid electric vehicle or a pure electric vehicle, main relays 40, 41 and pre-charge relay 42 are more preferably mechanical relays. In particular, main relays 40, 41 is more preferably a mechanical relay than pre-charge relay 42.

Current sensor 50 measures the current (specifically, current flowing through a path connecting battery 10 and the load) of battery 10. Current sensor 50 is, for example, a shunt resistor, and measures the current of battery 10 by converting the current flowing through the resistance element of the shunt resistor into a voltage. For example, since the resistance value of the resistance element of the shunt resistor is as small as several tens of microohms and the generated voltage is also small, current sensor 50 may include an amplifier circuit. Battery disconnection system 1 includes amplifier circuit 74 separately from the amplifier circuit.

As current sensor 50, other methods (as an example, a current sensor using a Hall element) can be used in addition to the shunt resistor (shunt method). However, from the viewpoint of ease of mounting to battery disconnection system 1, it is more preferable to use a shunt resistor (shunt system) that can be made smaller than a current sensor using a Hall element.

Pyrotechnic disconnection device 60 is a device for cutting off the current in battery 10. Specifically, pyrotechnic disconnection device 60 is provided on a path connecting battery 10 and the load, and is a device for disconnecting the path. Pyrotechnic disconnection device 60 is, for example, a pyrofuse.

Voltage measurement unit 75 measures the voltage of pre-charge resistor 43. In the first exemplary embodiment, as illustrated in FIG. 1, voltage measurement unit 75 includes first voltage sensor 72 that measures a voltage across pre-charge resistor 43 as a voltage of pre-charge resistor 43.

Communication interface 80 is an interface that communicates with a host system of battery disconnection system 1.

Control circuit 73 is a circuit for cutting off the current of battery 10, and is a circuit for detecting a failure of current sensor 50. Control circuit 73 is realized by, for example, a micro controller unit (MCU) or the like.

Control circuit 73 controls pyrotechnic disconnection device 60 on the basis of a measured value of current sensor 50 when main relay 40 is turned on (That is, during normal operation). Specifically, when the measured value of current sensor 50 satisfies a predetermined condition, control circuit 73 controls pyrotechnic disconnection device 60 to execute disconnection of the path connecting battery 10 and the load. The predetermined condition is not particularly limited, but is a condition that the measured value of current sensor 50 is a value corresponding to the current to disconnect the path. For example, control circuit 73 controls pyrotechnic disconnection device 60 via ignition circuit 71. Ignition circuit 71 is a circuit that controls pyrotechnic disconnection device 60 according to the output signal from control circuit 73 when the output signal from control circuit 73 is small and pyrotechnic disconnection device 60 cannot be driven only by control circuit 73. When pyrotechnic disconnection device 60 can be controlled by control circuit 73 alone, ignition circuit 71 may not be provided.

In addition, control circuit 73 detects the failure of current sensor 50 on the basis of the measured value of voltage measurement unit 75 when main relay 40 is turned off and pre-charge relay 42 is turned on (that is, when the inrush current countermeasure before the start of the normal operation is performed). Control circuit 73 can recognize that pre-charge relay 42 is turned on and the main relay is turned off when current flows through pre-charge resistor 43 and voltage measurement unit 75 measures a voltage equal to or higher than a predetermined value.

Control circuit 73 calculates a current from the measured value of first voltage sensor 72 and the resistance value of pre-charge resistor 43 during a period from when pre-charge relay 42 is turned on from off to when the pre-charge relay is turned off from on after a certain period of time (for example, 0.1 s), and compares the calculated current with the measured value of current sensor 50 to detect a failure of current sensor 50. For example, when the calculated current (that is, the current flowing through pre-charge resistor 43) substantially matches the measured value of current sensor 50 (that is, the current flowing through current sensor 50 (shunt resistor)), control circuit 73 determines that current sensor 50 does not fail. On the other hand, when they do not substantially match with each other, control circuit 73 detects a failure of current sensor 50. This is because when current sensor 50 does not fail, the current flowing through current sensor 50 and the current flowing through pre-charge resistor 43 substantially match with each other.

Note that the measured value of first voltage sensor 72 and the measured value of current sensor 50 are values measured at substantially the same timing. The timing of measuring the measured value of first voltage sensor 72 and the measured value of current sensor 50 is not particularly limited, but may be as early as possible after pre-charge relay 42 is turned on from off since smoothing capacity 20 is gradually charged and the flowing current decreases. In addition, an average value at a plurality of timings may be used as the measured value of first voltage sensor 72 and the measured value of current sensor 50.

Note that an example has been described in which control circuit 73 detects the failure of current sensor 50 by comparing the measured value of current sensor 50 with the current calculated from the measured value of voltage measurement unit 75, but the present invention is not limited thereto. For example, control circuit 73 may detect the failure of current sensor 50 by comparing the gradient of the temporal change of the measured value of current sensor 50 with the gradient of the temporal change of the measured value of voltage measurement unit 75. This is because, in the case of comparison of the measured value itself, the detection accuracy of current sensor 50 may be lowered due to the influence of an error in the resistance value or the like, but in the case of comparison of the gradient of the temporal change of the measured value, the gradient of the temporal change is less likely to be affected by an error in the resistance value or the like, and a decrease in the detection accuracy of current sensor 50 can be suppressed.

In addition, amplifier circuit 74 amplifies a signal of current sensor 50 when a failure of current sensor 50 is detected. That is, amplifier circuit 74 amplifies the signal of current sensor 50 when main relay 40 is turned off and pre-charge relay 42 is turned on (that is, when the inrush current countermeasure before the start of the normal operation is performed). When the inrush current countermeasure is performed, unlike the large current at the time of abnormality, the current flowing through current sensor 50 is small, and the measurement accuracy of current sensor 50 is poor. Therefore, at this time, the signal of current sensor 50 is amplified by amplifier circuit 74. Then, the signal of current sensor 50 amplified by amplifier circuit 74 is input to control circuit 73, and control circuit 73 detects the failure of current sensor 50 on the basis of the signal of current sensor 50 amplified as the measured value of current sensor 50. However, in a case where the signal of current sensor 50 is amplified and input to control circuit 73 during the normal operation, the signal may exceed the measurement range of control circuit 73. Therefore, amplifier circuit 74 is not used during the normal operation.

In addition, for example, when detecting a failure of current sensor 50, control circuit 73 notifies a host system of the abnormality via communication interface 80. As a result, it is possible to notify the driver or the like of the vehicle of the abnormality, and the safety can be enhanced.

As described above, battery disconnection system 1 includes main relay 40 connected between battery 10 and the load, pre-charge relay 42 and pre-charge resistor 43 connected in parallel with main relay 40 and connected in series, current sensor 50 that measures the current of battery 10, pyrotechnic disconnection device 60 for cutting off the current of battery 10, voltage measurement unit 75 that measures the voltage of pre-charge resistor 43, and control circuit 73. Control circuit 73 controls pyrotechnic disconnection device 60 based on the measured value of current sensor 50 when main relay 40 is turned on, and detects the failure of current sensor 50 based on the measured value of voltage measurement unit 75 when main relay 40 is turned off and pre-charge relay 42 is turned on.

In battery disconnection system 1, pre-charge relay 42 and pre-charge resistor 43 are provided, and pre-charge relay 42 is turned on before main relay 40 is turned on, and a current flows through pre-charge resistor 43, thereby taking a measure against an inrush current. In the present disclosure, pre-charge resistor 43 used as a countermeasure against the inrush current is also used to detect the failure of current sensor 50, so that the failure of current sensor 50 can be detected without providing a plurality of current sensors 50.

For example, control circuit 73 may control pyrotechnic disconnection device 60 to disconnect the path connecting battery 10 and the load when the measured value of current sensor 50 satisfies a predetermined condition.

As described above, in the battery disconnection system 1, when the measured value of current sensor 50 satisfies the predetermined condition (specifically, when a large current flows through current sensor 50), pyrotechnic disconnection device 60 can disconnect the path connecting battery 10 and the load.

For example, voltage measurement unit 75 may include first voltage sensor 72 that measures a voltage across pre-charge resistor 43 as the voltage of pre-charge resistor 43.

As described above, the voltage across pre-charge resistor 43 may be measured as the voltage of pre-charge resistor 43.

For example, control circuit 73 may calculate the current from the measured value of first voltage sensor 72 and the resistance value of pre-charge resistor 43, and compare the calculated current with the measured value of current sensor 50 to detect the failure of current sensor 50.

In this manner, the current flowing through pre-charge resistor 43 can be calculated from the voltage across pre-charge resistor 43 and the resistance value of pre-charge resistor 43, and when the calculated current flowing through pre-charge resistor 43 and the measured value of current sensor 50 (specifically, the current flowing through current sensor 50) are compared and do not substantially coincide with each other, it is possible to detect that current sensor 50 has failed.

For example, battery disconnection system 1 may further include communication interface 80 that communicates with a host system. For example, when detecting the failure of current sensor 50, control circuit 73 may notify the host system of the abnormality via communication interface 80.

According to this, it is possible to notify the host system of the failure of current sensor 50.

For example, battery disconnection system 1 may further include amplifier circuit 74 that amplifies a signal of current sensor 50 when detecting a failure of current sensor 50. For example, the signal of current sensor 50 amplified by amplifier circuit 74 may be input to control circuit 73, and control circuit 73 may detect a failure of current sensor 50 on the basis of the amplified signal of current sensor 50 as a measured value of current sensor 50.

When a failure of current sensor 50 is detected, a current flowing through pre-charge resistor 43 is small. For this reason, the current measured by current sensor 50 is also small, and there is a problem that the detection accuracy of the failure of current sensor 50 decreases. Therefore, by amplifying the signal of current sensor 50 by the amplifier circuit 74, the detection accuracy of the failure of current sensor 50 can be improved.

### Modification of First Exemplary Embodiment

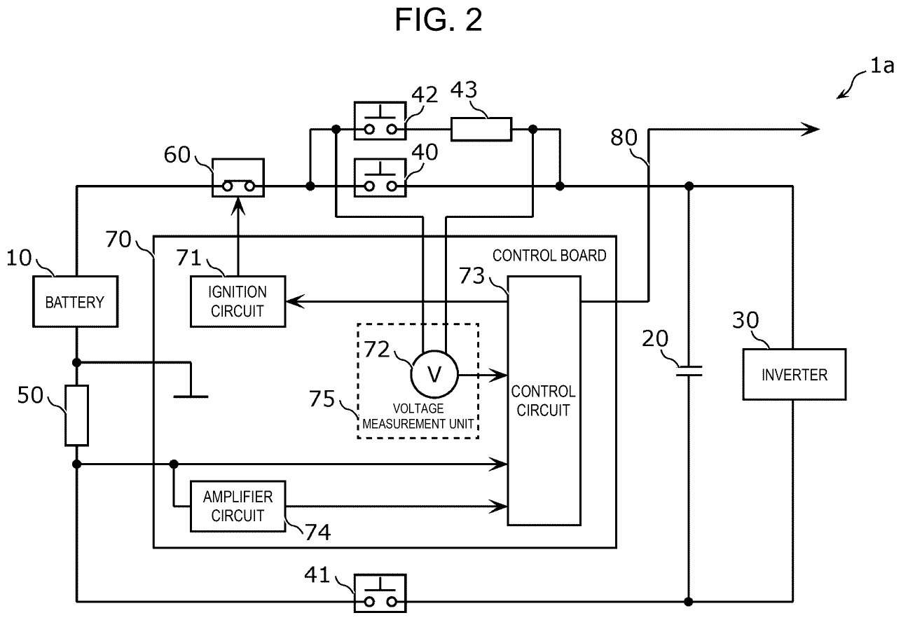

Next, battery disconnection system 1a according to a modification of the first exemplary embodiment will be described with reference to FIG. 2.

FIG. 2 is a configuration diagram illustrating an example of battery disconnection system 1a according to a modification of the first exemplary embodiment.

A modification of the first exemplary embodiment is different from the first exemplary embodiment in that voltage measurement unit 75 includes first voltage sensor 72 that measures, as a voltage of pre-charge resistor 43, a voltage across pre-charge relay 42 and pre-charge resistor 43 connected in series. Other configurations are the same as those of the first exemplary embodiment, and thus description thereof is omitted.

As in the modification of the first exemplary embodiment, the voltage across pre-charge relay 42 and pre-charge resistor 43 connected in series may be measured as the voltage of pre-charge resistor 43. This is because the on-resistance of pre-charge relay 42 is small and can be ignored, and the voltage across pre-charge relay 42 and pre-charge resistor 43 connected in series can be regarded as the voltage across pre-charge resistor 43.

Accordingly, control circuit 73 calculates the current from the measured value of first voltage sensor 72 and the resistance value of pre-charge resistor 43, and compares the calculated current with the measured value of current sensor 50 to detect the failure of current sensor 50.

As described above, the current flowing through pre-charge resistor 43 can be calculated from the voltage across pre-charge relay 42 and pre-charge resistor 43 connected in series and the resistance value of pre-charge resistor 43, and when the calculated current flowing through pre-charge resistor 43 and the measured value of current sensor 50 (specifically, the current flowing through current sensor 50) are compared and do not substantially coincide with each other, it is possible to detect that current sensor 50 has failed.

### Second Exemplary Embodiment

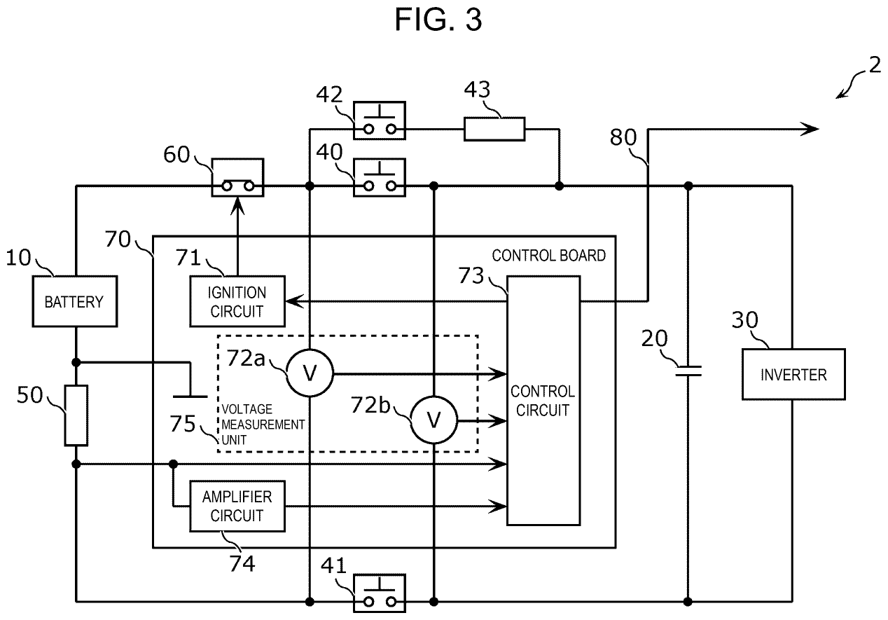

Next, battery disconnection system 2 according to a second embodiment will be described with reference to FIG. 3.

FIG. 3 is a configuration diagram illustrating an example of battery disconnection system 2 according to the second exemplary embodiment.

The second exemplary embodiment is different from the first exemplary embodiment in that voltage measurement unit 75 includes first voltage sensor 72a that measures the voltage of battery 10 and second voltage sensor 72b that measures the voltage of the load. Other configurations are the same as those of the first exemplary embodiment, and thus description thereof is omitted.

For example, first voltage sensor 72a measures, as the voltage of battery 10, a voltage between a node on battery 10 side of main relay 40 and pre-charge relay 42 and a node on battery 10 side of main relay 41. Note that first voltage sensor 72a may measure, as the voltage of battery 10, a voltage between a node on battery 10 side of pyrotechnic disconnection device 60 and a node on battery 10 side of main relay 41.

In addition, for example, second voltage sensor 72b measures, as the voltage of the load, a voltage between a node on the load side of main relay 40 and pre-charge resistor 43 and a node on the load side of main relay 41.

Since the on-resistances of pre-charge relay 42 and main relay 41 are small and can be ignored, the voltage of pre-charge resistor 43 corresponds to the difference between the measured value of first voltage sensor 72a (the voltage of battery 10) and the measured value of second voltage sensor 72b (the voltage of the load). Therefore, voltage measurement unit 75 measuring the voltage of battery 10 and the voltage of the load is equivalent to measuring the voltage of pre-charge resistor 43.

As described above, the voltage of battery 10 and the voltage of the load may be measured as the voltage of pre-charge resistor 43.

Accordingly, control circuit 73 calculates the voltage of pre-charge resistor 43 from the difference, calculates the current from the calculated voltage of pre-charge resistor 43 and the resistance value of pre-charge resistor 43, and detects the failure of current sensor 50 by comparing the calculated current with the measured value of current sensor 50.

As described above, the current flowing through pre-charge resistor 43 can be calculated from the difference and the resistance value of pre-charge resistor 43, and the calculated current flowing through pre-charge resistor 43 is compared with the measured value of current sensor 50 (specifically, the current flowing through current sensor 50). In a case where they do not substantially match, it is possible to detect that current sensor 50 has failed.

### Modification of Second Exemplary Embodiment

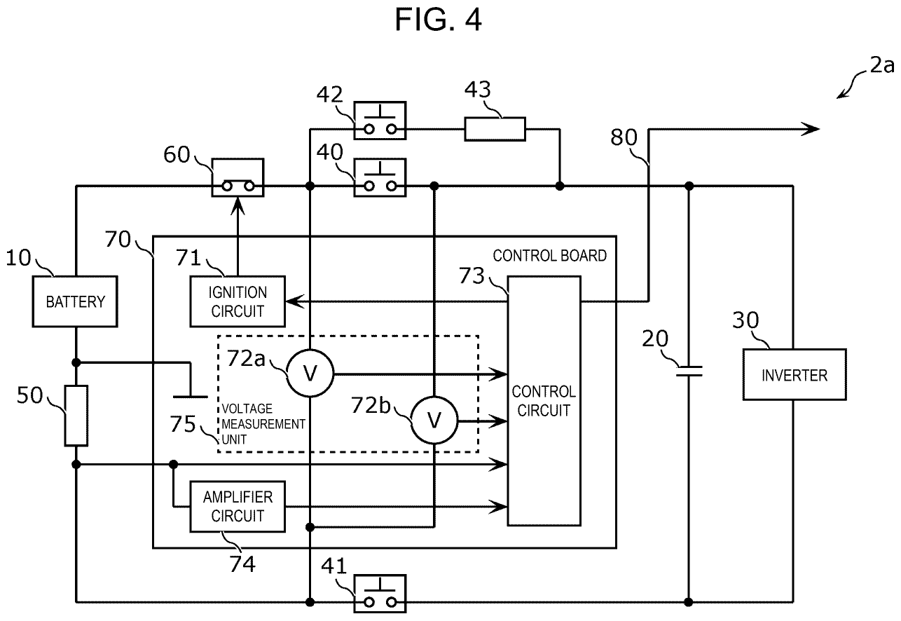

Next, battery disconnection system 2a according to a modification of the second exemplary embodiment will be described with reference to FIG. 4.

FIG. 4 is a configuration diagram illustrating an example of a battery disconnection system 2a according to a modification of the second exemplary embodiment.

The modification of the second exemplary embodiment is different from the second exemplary embodiment in that the reference potential of first voltage sensor 72a and the reference potential of second voltage sensor 72b are common. The other points are the same as those in the second exemplary embodiment, and thus the description thereof is omitted.

In order to simplify the circuit as compared with the configuration of the second exemplary embodiment, the reference potential of first voltage sensor 72a and the reference potential of second voltage sensor 72b may be common. Specifically, as illustrated in FIG. 4, each of the reference potential of first voltage sensor 72a and the reference potential of second voltage sensor 72b may be a potential of a node on battery 10 side of main relay 41. Alternatively, each of the reference potential of first voltage sensor 72a and the reference potential of second voltage sensor 72b may be a potential of a node on the load side of main relay 41. Each of the reference potential of first voltage sensor 72a and the reference potential of second voltage sensor 72b may be the ground potential of control board 70.

As described above, the reference potential of first voltage sensor 72a and the reference potential of second voltage sensor 72b may be common.

Accordingly, control circuit 73 calculates the voltage of pre-charge resistor 43 from the difference between the measured value of first voltage sensor 72a (the voltage of battery 10) and the measured value of second voltage sensor 72b (the voltage of the load), calculates the current from the calculated voltage of pre-charge resistor 43 and the resistance value of pre-charge resistor 43, and compares the calculated current with the measured value of current sensor 50 to detect the failure of current sensor 50.

As described above, the current flowing through pre-charge resistor 43 can be calculated from the difference and the resistance value of pre-charge resistor 43, and the calculated current flowing through pre-charge resistor 43 is compared with the measured value of current sensor 50 (specifically, the current flowing through current sensor 50). In a case where they do not substantially match, it is possible to detect that current sensor 50 has failed.

### Other Exemplary Embodiments

The exemplary embodiments have been heretofore described as examples of the technique according to the present disclosure. However, the technique according to the present disclosure is not limited to this, and can also be applied to exemplary embodiments in which changes, replacements, additions, omissions, and the like are made as appropriate. For example, the following modifications are also included in one exemplary embodiment of the present disclosure.

For example, in the above exemplary embodiment, an example in which the battery disconnection system includes amplifier circuit 74 has been described, but the battery disconnection system does not need to include amplifier circuit 74.

For example, in the above exemplary embodiment, an example in which the battery disconnection system includes communication interface 80 has been described, but the battery disconnection system does not need to include communication interface 80.

For example, the present disclosure can be realized not only as a battery disconnection system but also as a failure detection method including steps (processes) performed by components constituting the battery disconnection system.

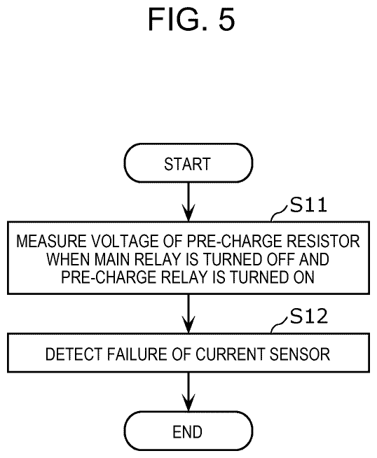

FIG. 5 is a flowchart illustrating an example of a failure detection method according to another exemplary embodiment.

A failure detection method is a failure detection method for a current sensor executed by a battery disconnection system including: a main relay connected between a battery and a load, a pre-charge relay and a pre-charge resistor connected in parallel with the main relay and connected in series, a current sensor that measures a current of the battery, and a pyrotechnic disconnection device that cuts off the current of the battery, and the failure detection method includes, as illustrated in FIG. 5, a step (step S11) of measuring a voltage of the pre-charge resistor when the main relay is turned off and the pre-charge relay is turned on, and a step (step S12) of detecting a failure of the current sensor based on a measured value measured in the measuring step.

For example, these steps included in the failure detection method may be executed by a computer (a computer system). The present disclosure can be implemented as a program for causing a computer to execute steps included in the failure detection method.

Furthermore, the present disclosure can be implemented as a non-transitory computer-readable recording medium such as a CD-ROM in which the program is recorded.

For example, in a case where the present disclosure is implemented by a program (software), each step is executed by executing the program using hardware resources such as a CPU, a memory, and an input/output circuit of a computer. That is, each step is executed by the CPU acquiring data from a memory, an input/output circuit, or the like and calculating the data, or outputting a calculation result to the memory, the input/output circuit, or the like.

Each component included in the battery disconnection system of the above exemplary embodiment may be realized as a dedicated or general-purpose circuit.

In addition, each component included in the battery disconnection system of the above exemplary embodiment may be realized as a large scale integration (LSI) which is an integrated circuit (IC).

In addition, the integrated circuit is not limited to the LSI, and may be realized by a dedicated circuit or a general-purpose processor. A programmable field programmable gate array (FPGA) or a reconfigurable processor in which connections and settings of circuit cells inside the LSI are reconfigurable may be used.

Further, if a circuit integration technology replacing the LSI appears due to the progress of the semiconductor technology or another derived technology, the components included in the battery disconnection system may be integrated using the technology.

In addition, the present disclosure includes a mode obtained by making various modifications conceivable by those skilled in the art to the exemplary embodiments, and a mode realized by arbitrarily combining components and functions of the exemplary embodiments without departing from the gist of the present disclosure.

### INDUSTRIAL APPLICABILITY

The present disclosure can be applied to a device that disconnects a current flowing through a current path.

### REFERENCE MARKS IN THE DRAWINGS

1, 1a, 2, 2a: battery disconnection system
10: battery
20: smoothing capacity
30: inverter
40, 41: main relay
42: pre-charge relay
43: pre-charge resistor
50: current sensor
60: pyrotechnic disconnection device
70: control board
71: ignition circuit
72, 72a: first voltage sensor
72b: second voltage sensor
73: control circuit
74: amplifier circuit
75: voltage measurement unit
80: communication interface

1. A battery disconnection system comprising:
a main relay connected between a battery and a load;
a pre-charge relay connected in parallel to the main:
a pre-charge resistor connected in parallel to the main, the pre-charge relay and the pre-charge resistor connected in series;
a current sensor that measures a current of the battery;
a pyrotechnic disconnection device for disconnecting the current of the battery;
a voltage measurement unit that measures a voltage of the pre-charge resistor; and
a control circuit, wherein
the control circuit controls the pyrotechnic disconnection device based on a measured value of the current sensor when the main relay is turned on, and detects a failure of the current sensor based on a measured value of the voltage measurement unit when the main relay is turned off and the pre-charge relay is turned on.

2. The battery disconnection system according to claim 1, wherein the control circuit controls the pyrotechnic disconnection device to disconnect a path connecting the battery and the load when the measured value of the current sensor satisfies a predetermined condition.

3. The battery disconnection system according to claim 1, wherein the voltage measurement unit includes a first voltage sensor that measures a voltage across the pre-charge resistor as the voltage of the pre-charge resistor.

4. The battery disconnection system according to claim 3, wherein the control circuit calculates a current from a measured value of the first voltage sensor and a resistance value of the pre-charge resistor, and compares the calculated current with the measured value of the current sensor to detect the failure of the current sensor.

5. The battery disconnection system according to claim 1, wherein the voltage measurement unit includes a first voltage sensor that measures a voltage across the pre-charge relay and the pre-charge resistor connected in series as the voltage of the pre-charge resistor.

6. The battery disconnection system according to claim 5, wherein the control circuit calculates a current from a measured value of the first voltage sensor and a resistance value of the pre-charge resistor, and compares the calculated current with the measured value of the current sensor to detect the failure of the current sensor.

7. The battery disconnection system according to claim 1, wherein
the voltage measurement unit includes:
a first voltage sensor that measures a voltage of the battery; and
a second voltage sensor that measures a voltage of the load, wherein
the voltage of the pre-charge resistor corresponds to a difference between a measured value of the first voltage sensor and a measured value of the second voltage sensor.

8. The battery disconnection system according to claim 7, wherein the control circuit calculates the voltage of the pre-charge resistor from the difference, calculates a current from the calculated voltage of the pre-charge resistor and a resistance value of the pre-charge resistor, and compares the calculated current with the measured value of the current sensor to detect the failure of the current sensor.

9. The battery disconnection system according to claim 7, wherein a reference potential of the first voltage sensor and a reference potential of the second voltage sensor are common.

10. The battery disconnection system according to claim 9, wherein the control circuit calculates the voltage of the pre-charge resistor from the difference, calculates a current from the calculated voltage of the pre-charge resistor and a resistance value of the pre-charge resistor, and compares the calculated current with the measured value of the current sensor to detect the failure of the current sensor.

11. The battery disconnection system according to claim 1, further comprising a communication interface that communicates with a host system.

12. The battery disconnection system according to claim 11, wherein the control circuit, when detecting the failure of the current sensor, notifies the host system of an abnormality via the communication interface.

13. The battery disconnection system according to claim 1, further comprising an amplifier circuit that amplifies a signal of the current sensor when the failure of the current sensor is detected.

14. The battery disconnection system according to claim 13, wherein
the signal of the current sensor amplified by the amplifier circuit is input to the control circuit, and
the control circuit detects the failure of the current sensor based on the amplified signal of the current sensor as the measured value of the current sensor.

15. A failure detection method of a current sensor executed by a battery disconnection system including a main relay connected between a battery and a load, a pre-charge relay and a pre-charge resistor connected in parallel to the main relay and connected in series, a current sensor that measures a current of the battery, and a pyrotechnic disconnection device that disconnects a current of the battery, the failure detection method comprising the steps of:
measuring a voltage of the pre-charge resistor when the main relay is turned off and the pre-charge relay is turned on; and
detecting a failure of the current sensor based on the measured values measured in the step of measuring.
